(19) United States
(12) Patent Application Publication
(10) Pub. No.: US 2026/0083005 A1
(43) Pub. Date: Mar. 19, 2026

(54) HOUSING, LEADFRAME COMPOSITE AND MANUFACTURING METHOD

(71) Applicant: ams-OSRAM International GmbH, Regensburg (DE)

(72) Inventor: Karlheinz Arndt, Bad Abbach (DE)

(21) Appl. No.: 19/108,674

(22) PCT Filed: Aug. 9, 2023
(86) PCT No.: PCT/EP2023/072069

§ 371 Date: Mar. 4, 2025

(30) Foreign Application Priority Data
Sep. 15, 2022 (DE) 10 2022 123 579.3

(51) Int. Cl. H01L 25/16; H01L 21/48; H01L 23/00; H01L 23/495; H10H 29/20

(52) U.S. Cl. CPC H10W 90/00; H10H 29/20; H10W 70/048; H10W 70/421; H10W 90/811; H10W 72/50

(57) ABSTRACT

In an embodiment a housing includes a first leadframe part and a second leadframe part and a housing body mechanically connecting the first and second leadframe parts to one another, wherein each first and second leadframe part has a mounting area on an inner side and each has an outer side opposite the inner side, wherein the first leadframe part has at least one solder control point and the second leadframe part has at least two solder control points, wherein each solder control point is formed as a recess at an associated outer side and is accessible from an outer side wall of the housing, and wherein the solder control points of the second leadframe part and the at least one solder control point of the first leadframe part are located on mutually opposite outer side walls of the housing body and are arranged completely offset relative to one another so that the solder control points are free of an overlap in a direction parallel to a main axis.

### CROSS-REFERENCE TO RELATED APPLICATIONS

This patent application is a national phase filing under section 371 of PCT/EP2023/072069, filed Aug. 9, 2023, which claims the priority of German patent application no. 102022123579.3, filed Sep. 15, 2022, each of which is incorporated herein by reference in its entirety.

### TECHNICAL FIELD

A housing for an optoelectronic semiconductor chip and a leadframe composite-are provided. In addition, a manufacturing method for such a housing is provided.

### SUMMARY

Embodiments provide a housing that is resistant to thermal loads.

According to at least one embodiment, the housing is configured for at least one optoelectronic semiconductor chip. The semiconductor chip or semiconductor chips are, for example, light-emitting diode chips, or LED chips for short, and/or laser diode chips, or LD chips for short. Several different types of optoelectronic semiconductor chips may be combined in the housing, for example, optoelectronic semiconductor chips for generating different colors of light, such as red, green and yellow.

According to at least one embodiment, the housing comprises a first leadframe part and a second leadframe part. Additional leadframe parts may be present. The term leadframe part refers in particular to metallic bodies which are, for example, stamped and/or etched and/or cut from a sheet metal. All leadframe parts are preferably made of the same base material, in particular a copper sheet or a copper foil. The leadframe parts can be provided with at least one metallic coating which, however, is preferably significantly thinner than the base material.

According to at least one embodiment, the housing comprises a housing body. The housing body is made of at least one electrically insulating material and is based, for example, on a plastic. The housing body may be based on an epoxy or silicone. It is possible that the housing body contains additives, such as particles or fibers to adapt thermal expansion or to improve mechanical stability. The housing body is preferably opaque.

According to at least one embodiment, the housing body mechanically connects the first and second leadframe parts and optional further leadframe parts to each other. That is, without the housing body, the leadframe parts would not be mechanically fixed relative to each other. For example, the housing body partially or completely covers the side surfaces of the leadframe parts, at least within the housing body. In the lateral direction, for example, the leadframe parts are only exposed from the housing body on outer side walls of the housing.

According to at least one embodiment, the first leadframe part has a mounting area for attaching a semiconductor chip and/or for attaching an electrical connecting means. The semiconductor chip is in particular the at least one optoelectronic semiconductor chip, but the semiconductor chip can also be another type of semiconductor chip, for example, a control chip for the optoelectronic semiconductor chip or a protective chip, for example, to protect against damage caused by electrostatic discharge, or ESD for short. In the mounting area, the first leadframe part preferably has its full thickness.

In the same way, the second leadframe part and/or the at least one optional further leadframe part can also have a mounting area for at least one semiconductor chip, at least one optoelectronic semiconductor chip and/or at least one electrical connecting means. The electrical connecting means is, for example, a bonding wire.

For example, the mounting areas are located on an inner side of the leadframe parts. This means that the mounting areas can be located inside the housing.

According to at least one embodiment, the mounting areas are accessible through the housing body. For this purpose, the housing body has, for example, one or more recesses in which the leadframe parts are exposed. Alternatively, the housing body is only as flat or approximately as flat as the leadframe parts, so that the housing base body leaves the mounting areas exposed due to its low thickness.

The housing base body can be constructed in one or more parts.

According to at least one embodiment, the leadframe parts each have an outer side opposite the inner side. Like the inner sides, the outer sides are preferably main sides, i.e. the largest sides, of the leadframe parts. The outer sides are configured for external assembly of the housing, for example, by soldering.

According to at least one embodiment, the first and second leadframe parts each have one or more solder control points, also referred to as solder control structures. The solder control points are each formed by a recess in the respective leadframe part from the associated outer side. Furthermore, the solder control points are accessible from an outer side wall of the housing. This means that in the uninstalled state of the housing, i.e. when the housing is not yet soldered to an external electrical carrier, the solder control points can be seen from the side walls. The solder control points are provided with at least one metal coating, for example, so that the solder control points are configured to be wettable for a solder.

According to at least one embodiment, the solder control points are located on opposite outer side walls of the housing. In other words, the solder control points are located on side walls facing away from each other.

According to at least one embodiment, the solder control points are arranged offset to one another. This means, for example, that the solder control points only partially overlap or do not overlap at all when viewed in vertical projection onto one of the outer side walls in question.

In at least one embodiment, the housing is provided for at least one optoelectronic semiconductor chip and comprises a first leadframe part and a second leadframe part as well as a housing body which mechanically connects the first and the second leadframe part to one another,
wherein
the first and the second leadframe parts each have a mounting area on an inner side and each have an outer side opposite the inner side,
the first and the second leadframe parts each have at least one solder control point, which is formed by a recess from the associated outer side and is accessible from an outer side wall of the housing, and
the solder control points are located on mutually opposite outer side walls and are arranged offset relative to one another.

In other words, a housing with staggered solder control structures is provided. With such a housing, a higher housing tightness, higher mechanical load capacity of QFN panels during production and a lower risk for the formation of gaps and delamination between metal and housing plastic can be achieved.

Quad-flat no-leads, QFN, housings are often not completely free of gaps and delaminations between the metal leadframe and a housing plastic, such as an epoxy mold compound. In some cases, the gaps already occur during the production of a panel, comprising a large number of housing units to be singulated, and in some cases only during further processing. Particularly stressful processes are waterjet deflashing after molding, wire bonding and casting if panels are heavily bent and need to be pressed flat, as well as sawing.

It is possible for etched solder control structures to be created in such a way that elongated pockets—also known as tie bars—are etched into webs connecting leadframe units, which are positioned symmetrically to the later sawing track, for example. This means that on the finished component, after sawing, etched solder control structures on opposite side surfaces of the resulting housing are then exactly opposite each other.

In the housing described herein, the solder control structures are not etched in continuous tie bars. The etched pockets are not symmetrical to the later sawing track. On the finished component, the solder control structures are therefore not exactly opposite each other, but are laterally offset.

In particular the following effects may be used in the housing described herein, either individually or in combination:
The two largest leadframe parts, also known as pads, for example an LED pad and an IC pad, are no longer coupled to each other with a direct line of force, but are connected to each other in a comparatively mechanically flexible manner.—Each individual component in the panel composite has a circumferential semi-etched tie bar frame, which, for example, creates a grid structure due to the regular grid-like arrangement, which gives the entire panel greater rigidity against vibrations.
The semi-etched circumferential tie bar frame is left in full material thickness at certain points. This allows the panel to be reinforced against buckling in particularly sensitive areas.
These areas with full material thickness can also serve as saw markings.

For example, a weak spot in a QFN LED component is a joint between the LED pad and the IC pad. Thanks to the offset solder control structures, two neighboring components in the panel assembly no longer pull against each other. At the same time, the thickening applied in places on the circumferential tie bar frame protects the connections between the LED pad and the IC pad against damaging bending forces. The bending forces are caused, for example, by vibrations during waterjet deflashing or when a bent panel has to be pressed flat. The panel bending itself occurs, for example, when the panel cools down due to different thermal expansion coefficients. The reinforcements in the tie bar frame protect the sensitive areas in the panel during production.

According to at least one embodiment, the solder control points are arranged completely offset to one another. This means, for example, that the solder control points are arranged without overlapping in a direction parallel to a main axis. In other words, the solder control points do not overlap with one another when they are projected onto one another in the direction parallel to the main axis.

The main axis runs, for example, perpendicular to the opposing outer side walls having the solder control points when viewed onto the outer sides. Alternatively or additionally, the main axis can run parallel to further side walls, whereby the further side walls are oriented transversely to the opposing outer side walls with the solder control points. Furthermore, the main axis can intersect a center point of the housing, seen in plan view of the outer sides. In the case of a square housing, the center point is in particular a diagonal intersection point or a center of area, as seen in plan view of the outer sides.

In other words, the solder control points are at different distances from a common reference surface of the housing, the common reference surface being, for example, one of the further side walls. A difference in distance from the reference surface is, for example, at least as great as a width of the solder control points along the outer side walls having the solder control points.

According to at least one embodiment, a first number N1 of solder control points of the first leadframe part differs from a second number N2 of solder control points of the second leadframe part. For example, |N1-N|=1 or |N1-N2|=2. Alternatively or additionally, N1<N2. For example, N1=1 and N2 =2, or N1=1 and N2 =3, or N1=2 and N2=3.

For example, the first leadframe part has a larger area than the second leadframe part when viewed from the inner sides.

According to at least one embodiment, the solder control points of the first and second leadframe parts are located exclusively on the two outer side walls opposite each other. This means that the further side walls are then free of solder control points. Alternatively, the further side walls can be provided with further solder control points, whereby the further solder control points can optionally also be arranged offset from one another.

According to at least one embodiment, the outer sides of the first and second leadframe parts only extend to these outer side walls. In other words, the first and second leadframe parts can end at a distance from the further side walls, as seen in plan view of the outer sides.

According to at least one embodiment, the first and second leadframe parts are flush with the housing body on the outer sides and/or on the opposing outer side walls. Thus, the outer sides and a housing bottom side of the housing body can lie in a common plane.

According to at least one embodiment, the housing further comprises one or more further leadframe parts. The at least one further leadframe part is made, for example, from the same leadframe composite as the first and second leadframe parts.

According to at least one embodiment, there is at least one tie bar on the further leadframe part, on one or more of the further leadframe parts or on all of the further leadframe parts. By means of the tie bars, the leadframe parts can be mechanically connected to each other within the leadframe composite if no housing body is yet present.

According to at least one embodiment, the at least one tie bar of the further leadframe parts is only exposed on a further outer side wall extending transversely to the outer side walls with the solder control points. The side walls with the solder control points can therefore be free of the tie bars.

According to at least one embodiment, the further leadframe part or one or more of the further leadframe parts is connected to the first and/or the second leadframe part by means of at least one further tie bar. In other words, the further tie bar can be used to realize a direct mechanical connection between the first and/or second leadframe part and the at least one further leadframe part in question.

In addition, a leadframe composite for housings as described in connection with one or more of the above embodiments is provided. Features of the leadframe composite are therefore also disclosed for the housing and vice versa.

In at least one embodiment, the leadframe composite comprises a plurality of leadframe units for one housing each. Each of the leadframe units comprises a first leadframe part and a second leadframe part,
wherein per leadframe unit:
the first and second leadframe parts each have a mounting area on an inner side and each have an outer side opposite the inner side, it being possible for each of the inner sides to be larger than the associated outer side,
the first and second leadframe parts each have at least one solder control point which is formed by a recess from the outer side, and
the solder control points are located on opposite sides and are offset from each other.

According to at least one embodiment, each of the leadframe units has a circumferential frame that partially or completely surrounds it. This means that the frame can surround the leadframe unit in question all around as a closed line. Viewed from above, the frame is rectangular, for example. Taken together, the frames of the leadframe units can form a grid. Adjacent leadframe units each share one strut of the frame.

According to at least one embodiment, a width of the frame is at least 30 μm or at least 50 μm or at least 100 μm when viewed from above on the outer sides and/or inner sides and alternatively or additionally at most 0.3 mm or at most 200 μm.

For example, a thickness of the leadframe composite is at least 100 μm or at least 150 μm or at least 190 μm and/or at most 0.8 mm or at most 0.5 mm or at most 320 μm.

According to at least one embodiment, the frames each have thickenings with full material thickness of the leadframe composite and the thickenings are arranged in extension of a gap between the associated first and second leadframe parts. It is possible that a width of the frame does not change in the area of the thickenings, seen in plan view on the inner side and/or the outer side.

According to at least one embodiment, a length of the thickenings is at least twice a width of the associated gap, as seen onto the outer sides. Alternatively or additionally, this value is at most six times or at most three times. Such thickenings make it possible to prevent bending of the leadframe composite in the area of the gaps.

According to at least one embodiment, the frame has at least one further thickening extending from at least one of the solder control points. The further thickening extends, for example, in the extension of a gap between the first leadframe part and several further leadframe parts.

According to at least one embodiment, a solder control point frame of one of the leadframe units extends between the solder control points of one of the leadframe parts of a directly adjacent leadframe unit when viewed from above onto the outer sides. This means that in the leadframe composite, the solder control points and/or their borders are not yet completely divided between the leadframe units, but can extend across two neighboring leadframe units. Such an area in which the borders extend across two adjacent leadframe units is, for example, narrower than a separation track between the leadframe units in question.

According to at least one embodiment, the solder control points are connected to each other on a common side of two directly adjacent leadframe units by means of one or more transverse bars. The transverse bar can be part of the frame around the leadframe units in question. The at least one transverse bar extends, for example, transversely, in particular perpendicularly, to the associated main axis. The at least one transverse bar is, for example, limited to the separation track between the leadframe units in question.

According to at least one embodiment, the at least one transverse bar is set back from the outer sides. This means that the leadframe composite does not have its full thickness in the area of the at least one transverse bar. The at least one transverse bar can be flush with the inner sides, but does not extend to the outer sides.

According to at least one embodiment, viewed from the outer sides, the recesses for the solder control points are each limited to one of the leadframe units. This means, for example, that the recesses do not touch or cross any boundaries between adjacent leadframe units.

According to at least one embodiment, the solder control points are arranged mirror-symmetrically with respect to the main axis of the leadframe unit in question when viewed from above onto the outer sides. It is possible that only one of the solder control points of the leadframe unit in question lies on the main axis or that the main axis intersects only one of the solder control points.

In addition, a method of manufacturing a housing as described in connection with one or more of the above embodiments is provided. Features of the housing are therefore also disclosed for the leadframe composite as well as the method, and vice versa.

In at least one embodiment, a method of manufacturing housings for at least one optoelectronic semiconductor chip comprising the following steps, for example in the order given:

### Providing a Leadframe Composite,

molding a housing base body to the leadframe units of the leadframe composite, and
separating the housing base body and the leadframe composite to form the individual housings, so that each of the separated housings comprises the leadframe parts of one of the leadframe units and a housing body.

According to at least one embodiment, the frames, the solder control point frames and/or the transverse bars are partially or completely in a separation track during singulation. This means that the frames, the solder control point frames and/or the transverse bars are no longer present in the finished housing.

Further disclosed is an optoelectronic semiconductor component manufactured by a method as described in connection with one or more of the above embodiments. Features of the optoelectronic semiconductor component are therefore also disclosed for the housing, the leadframe composite and the method, and vice versa.

In at least one embodiment, the optoelectronic semiconductor component comprises a housing and one or more optoelectronic semiconductor chips, such as LED chips. Furthermore, at least one further semiconductor chip, such as a drive chip, may be present.

### BRIEF DESCRIPTION OF THE DRAWINGS

In the following, a housing described herein, a leadframe composite described herein, a method described herein and an optoelectronic semiconductor component described herein are explained in more detail with reference to the drawing by means of exemplary embodiments. Identical reference signs indicate identical elements in the individual figures.

However, no references are shown to scale; rather, individual elements may be shown in exaggerated size for better understanding.

FIG. 1 shows schematic perspective views of an embodiment of an optoelectronic semiconductor component described herein;

FIGS. 2 and 3 show schematic perspective views of a modification of a housing;

FIG. 4 shows a schematic top view of a modification of a leadframe composite with a modification of a housing;

FIG. 5 shows a schematic perspective view of an embodiment of a housing described herein;

FIGS. 6 and 7 show schematic perspective views of leadframe units for embodiments of housings described herein;

FIG. 8 shows a schematic perspective view of an embodiment of an optoelectronic semiconductor component described herein;

FIGS. 9 to 12 show schematic top views of embodiments of leadframe composites described herein;

FIG. 13 shows a schematic perspective view of an embodiment of a housing described herein;

FIGS. 14 to 16 show schematic perspective views of leadframe units for embodiments of housings described herein;

FIGS. 17 to 21 show schematic perspective views and plan views of embodiments of leadframe composites described herein;

FIG. 22 shows a schematic top view of an embodiment of a housing described herein; and

FIG. 23 shows a schematic block diagram of an embodiment of a method for manufacturing housings described herein.

### DETAILED DESCRIPTION OF ILLUSTRATIVE EMBODIMENTS

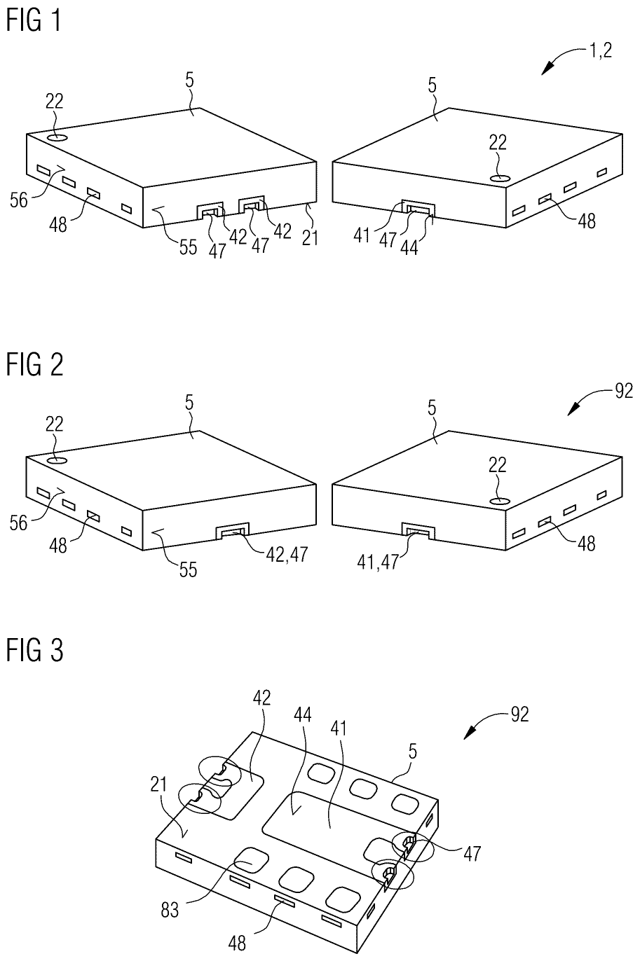

FIG. 1 shows an example of a housing 2 in two views of different, opposing outer side walls 55. The housing 2 comprises a first leadframe part 41 and a second leadframe part 42. Further leadframe parts 83 are optionally present, of which only associated tie bars 48 on further outer side walls 56 can be seen in FIG. 1. The leadframe parts 41, 42 are embedded in a housing body 5. It is possible that, for example, an orientation marking 22 is provided on an upper side of the housing body 5. The housing 2 contains at least one optoelectronic semiconductor chip, not visible in FIG. 1.

The leadframe parts 41, 42 are each provided with at least one solder control point 47. The solder control points 47 are located on the side walls 55 and are formed by recesses from outer sides 44 of the leadframe parts 41, 42 on a housing bottom side 21. The solder control points 47 on the side walls 55 are offset from one another. In projection onto the side walls 55, the solder control points 47 therefore do not overlap.

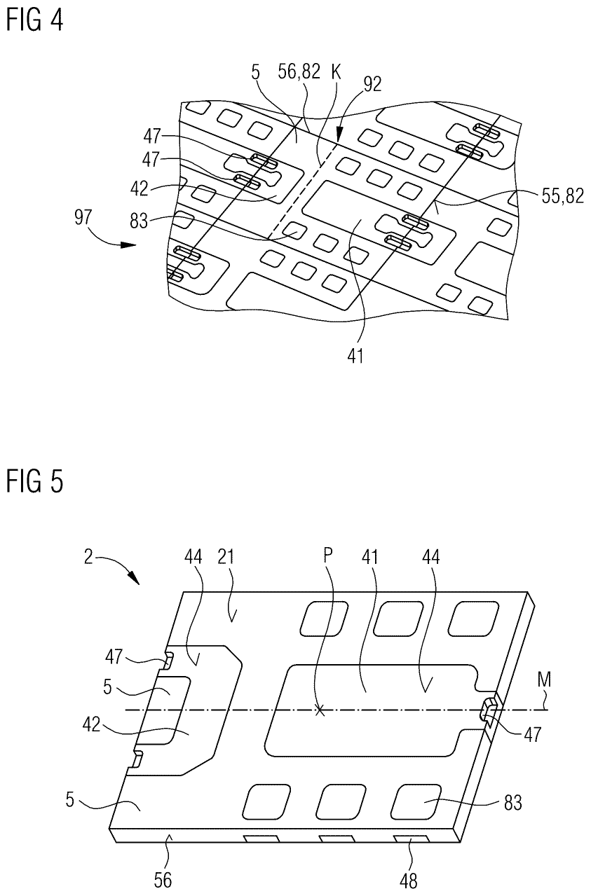

In the modification 92 of a housing as shown in FIGS. 2 and 3, on the other hand, the solder control points 47 are located at the same positions on the side walls 55. This is due to the fact that the solder control points 47 are manufactured across neighboring leadframe units 4 in a modified leadframe composite 97, see FIG. 4. As a result, neighboring leadframe units 4 are mechanically strongly coupled to one another on the sides with the solder control points 47 and are connected to one another in a flexurally rigid manner.

Potential bending points of the leadframe composite 97 are thus located along lines K between the leadframe parts 41, 42, as the leadframe composite 97 is mechanically weakest here. Due to the offset arrangement of the solder control points 47, as shown in FIG. 1 and FIG. 5, the adjacent leadframe units 4 can be mechanically decoupled from each other to a considerable extent, and the risk of delamination of material of the housing body 5 from the leadframe parts 41, 42 can be reduced.

FIGS. 5 to 7 show a further example of the housing 2 and the associated leadframe unit 4. The housing body 5 can be as thick as the leadframe parts 41, 42. It is possible that a further housing body, not shown, is present.

Viewed from the outer side 44, which is configured for solder mounting of the housing 2, the larger first leadframe part 41 is elongate-rectangular in shape with rounded corners, the solder control point 47 being a lateral extension of this rectangle. The smaller second leadframe part 42 is U-shaped and is provided with two solder control points 47. The solder control point 47 of the first leadframe part 41 is intersected by a main axis M, which is also an axis of mirror symmetry, and lies between the solder control points 47 of the second leadframe part 42. The main axis M is perpendicular to the side walls 55 and runs through a center point M of the housing 2, as seen onto the housing bottom side 21.

A plurality of the further leadframe parts 83 are optionally arranged on both sides along the first leadframe part 41. Each of the further leadframe parts 83 can be provided with one of the tie bars 48. Optionally, a corner extension 84 is attached to each of the two further leadframe parts 83, which are located closest to the second leadframe part 42, in order to mechanically reinforce corner regions of the housing body 5. It is possible that the further leadframe parts 83 on the outer sides 4 are all the same size. The further leadframe parts 83 can all be smaller than the first and second leadframe parts 41, 42.

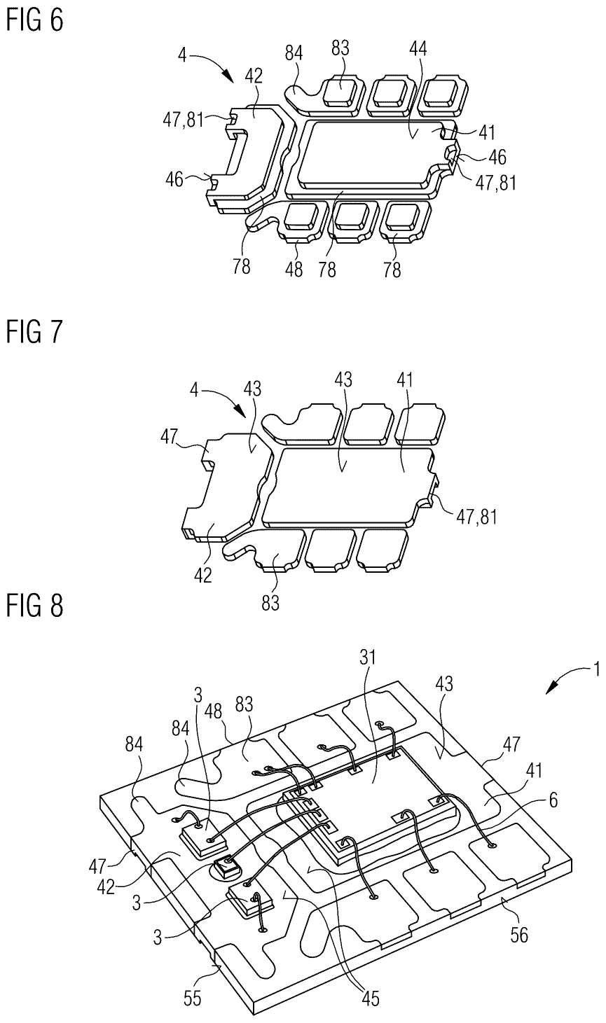

The leadframe parts 41, 42, 83 are half-etched, see FIGS. 6 and 7. This means that the inner sides 43 are larger than the outer sides 44. This means that there is a respective protrusion 78 of the inner sides 43 around the associated outer sides 44. In the area of the protrusion 78, the leadframe parts 41, 42, 83 have only approximately half the thickness. Except at the solder control points 47, the protrusion 78 can extend all around the respective leadframe part 41, 42, 83. Surfaces facing the outer sides 44 and side surfaces of the protrusion 78 are preferably completely covered with the housing body 5, so that only one side surface of each of the tie bars 48 is exposed during separation and is visible on the side walls 56.

Furthermore, FIG. 6 schematically shows that the solder control points 47 can be provided with a metal coating 81 in order to facilitate wetting with a solder.

In all other respects, the statements to FIGS. 1 to 4 apply in the same way to FIGS. 5 to 7, and vice versa.

FIG. 8 shows an example of an optoelectronic semiconductor component 1. Several optoelectronic semiconductor chips 3 are located on the inner side 43 of the second leadframe part 42. A further semiconductor chip 31, for example a driver chip for the optoelectronic semiconductor chips 3, is located on the inner side 43 of the first leadframe part 41. The chips 3, 31 are mounted in mounting areas 45 and are connected to each other and to the leadframe parts 41, 42, 83 by means of electrical connecting means 6, such as bonding wires.

Optionally, the housing body 5 can have recesses for the chips 3, 31, not shown.

It is optionally possible that the second leadframe part 42 also has corner extensions 84.

In all other respects, the comments on FIGS. 1 to 7 apply in the same way to FIG. 8, and vice versa.

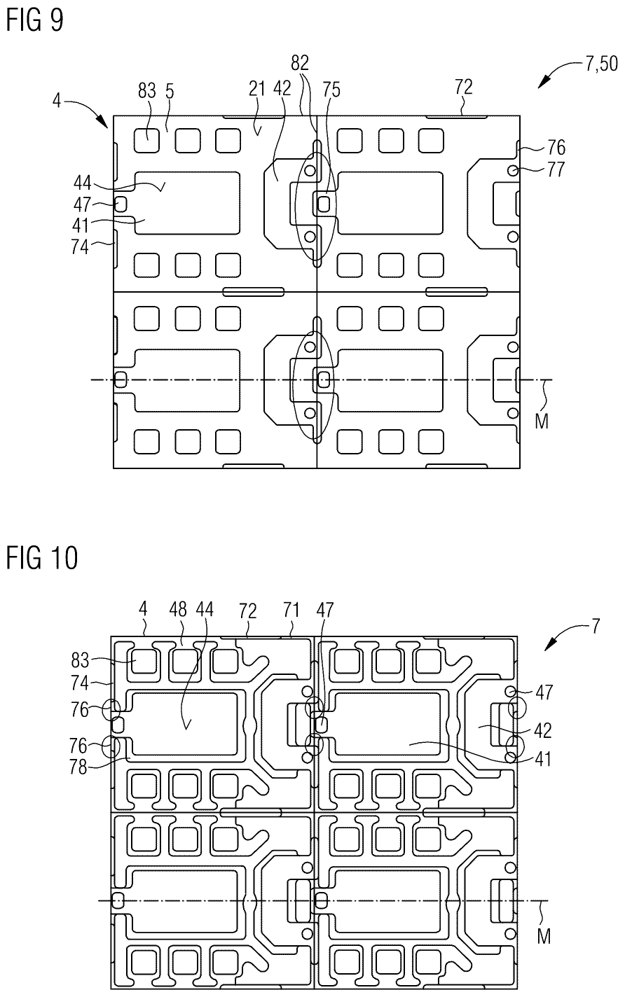

FIGS. 9 and 10 show an example of a leadframe composite 7 for housings 2, in each case with a view onto the outer sides 44, wherein a housing base body 50 for the housing bodies 5 is shown in FIG. 9 but not in FIG. 10. The leadframe composite 7 comprises a plurality of the leadframe units 4, which are separated from one another by separation center lines 82; the separation center lines 82 need not have any representational correspondence and can thus be imaginary or construction lines. The housing base body 50 extends contiguously over the leadframe units 4.

In particular, it can be seen in FIG. 9 that semi-etched recesses 77 are provided for the solder control points 47 from the outer sides 44. The recesses 77 are, for example, each limited to one of the leadframe units 4 and thus do not intersect or touch the separation center lines 82, see the highlighting in FIG. 9. The recesses 77 have lateral surfaces extending transversely, in particular perpendicularly or approximately perpendicularly to the outer sides 44.

It can also be seen in FIG. 9 that optional thickenings 72, 74 run along the separation center lines 82 and extend to the housing bottom side 21. The thickenings 72 run parallel to the main axis M, the further thickenings 74 run perpendicular to the main axis M. The further thickenings 74 extend from the solder control points 47 of the second leadframe part 42 and extend between the further leadframe parts 83.

The recesses 77 are surrounded by solder control point frames 75, which extend to the outer sides 44 with the full material thickness of the leadframe composite 7. The solder control point frames 75 each extend over two adjacent leadframe units 4.

In FIG. 10, it can be seen that transverse bars 76 are provided between the solder control points 47 of two adjacent leadframe units 4 along one of the separation center lines 82, see the highlighting in FIG. 10. The transverse bars 76 connect the solder control point frames 75 of the solder control points 47 to each other. The solder control points 47 concerned thus form a group, according to the example of FIGS. 9 and 10 in each case groups of three.

For example, the transverse bars 76 do not extend to the outer side 44. That is, the transverse bars 76 may be semi-etched regions of the leadframe composite 7.

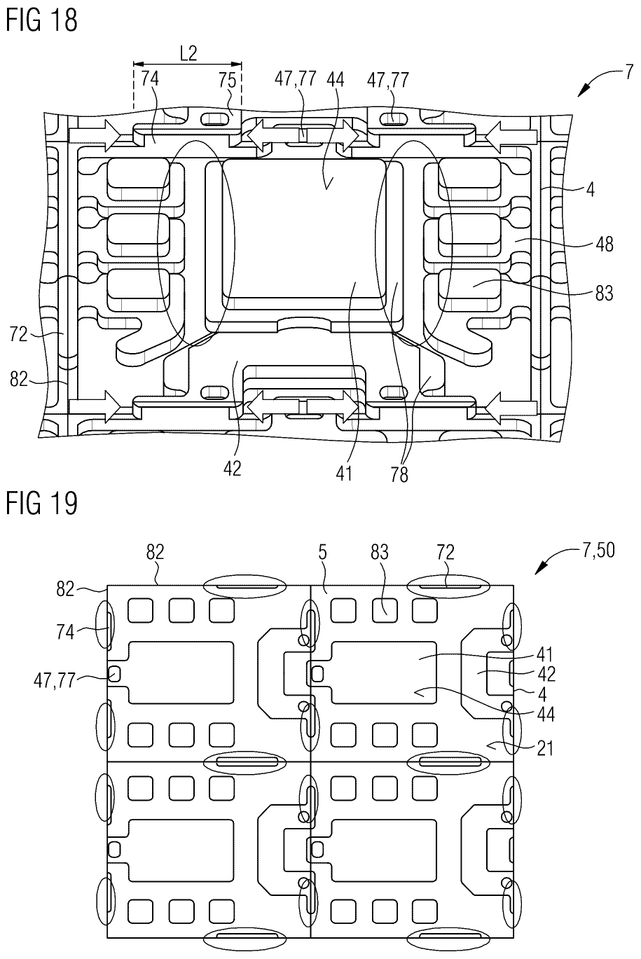

It can also be seen in FIG. 10 that the leadframe units 4 are each completely enclosed by a frame 71. The frames 71 together form a network that extends contiguously over the leadframe composite 7. The frames 71 include the reinforcements 72, 74 and the transverse bars 76. It can be seen in FIG. 10 that the reinforcements 72, 74 increase the thickness of the frame 71 in places, but do not widen the frame 71. The reinforcements 72, 74 are explained in more detail below, see in particular FIGS. 17 and 18.

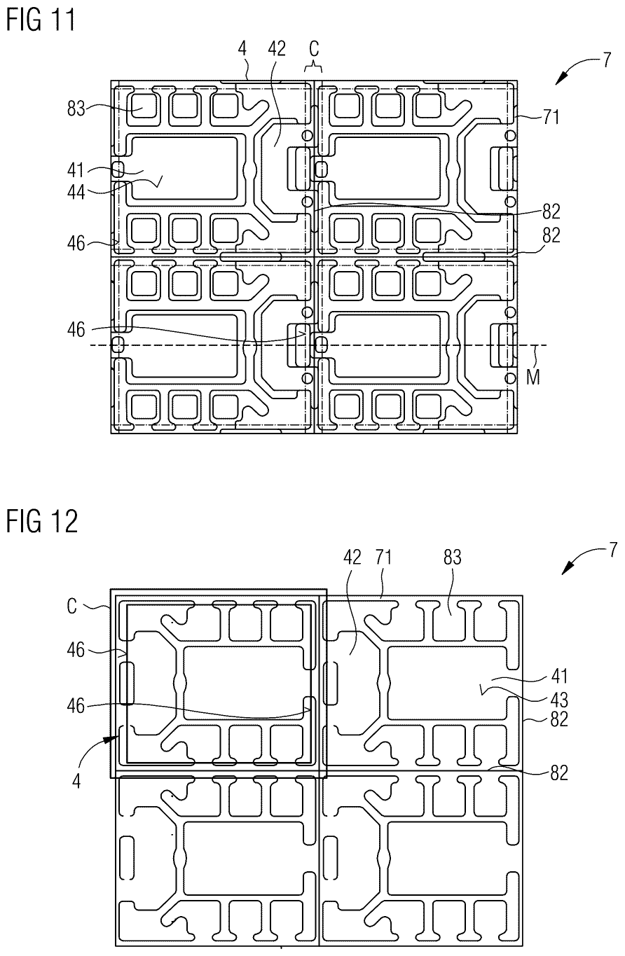

FIGS. 11 and 12 illustrate a cutting of the leadframe composite 7 from FIGS. 9 and 10, whereby the housing base body 50 is not drawn in FIG. 11 for better representation. Cutting to form the housings 2 takes place along the separation center lines 82, for example by means of sawing. Due to a width of the saw blade, separation tracks C result. A width of the separation tracks C is, for example, between 0.2 mm and 0.5 mm, in particular 0.3 mm.

The frames 71 are completely removed by cutting them apart. This means that there are no more reinforcements 72, 74 or transverse bars 76 in the finished housings 2. In addition, the parts of the solder control point frames 75 located in the separation tracks C are removed so that the recesses 77 are exposed at the sides. The side surfaces 55, 56 and border sides 46 of the leadframe parts 41, 42 with the solder control points 47 are thus created with the separation.

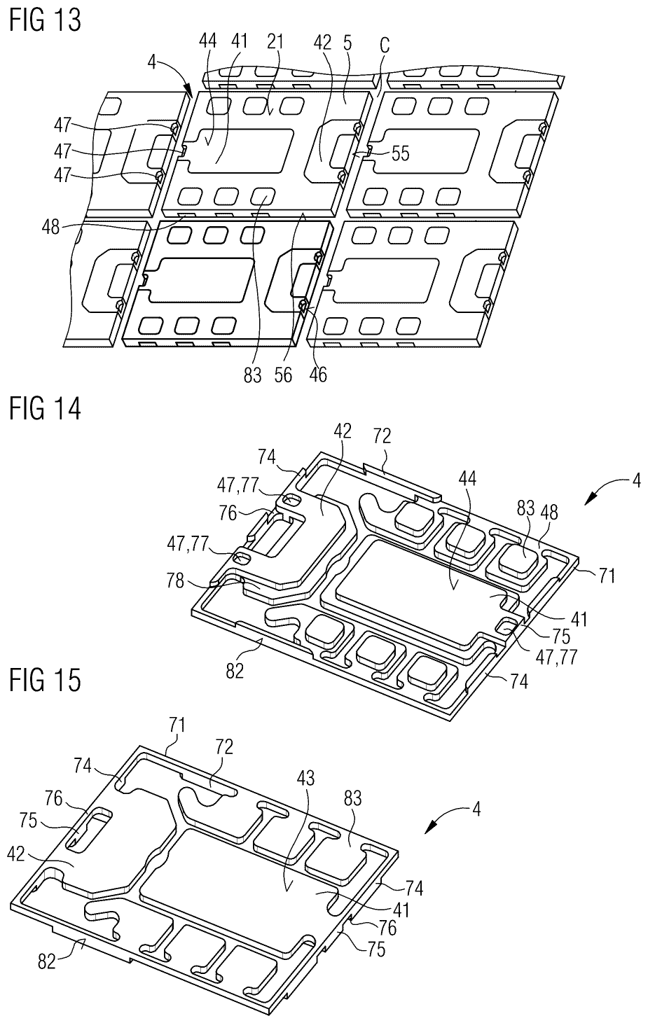

The resulting housings 2 can be seen in FIG. 13.

In all other respects, the explanations relating to FIGS. 1 to 8 apply in the same way to FIGS. 9 to 13, and vice versa.

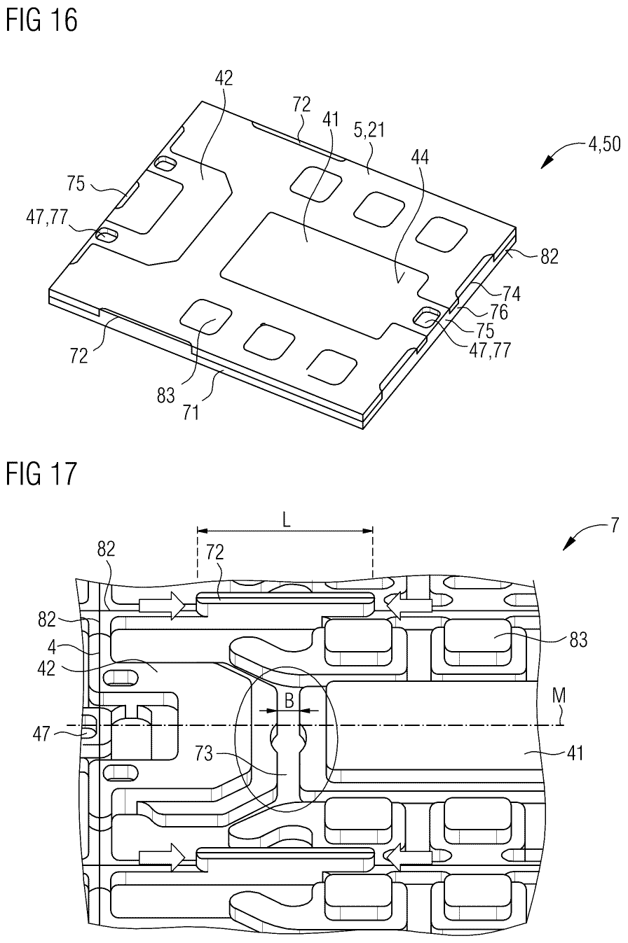

FIGS. 14 to 16 each show a leadframe unit 4 as used in connection with FIGS. 9 to 13. However, the areas eliminated by the separation are still drawn, so that the separation tracks C are not represented in FIGS. 14 to 16. The leadframe unit 4 is thus drawn in FIGS. 14 to 16 up to and including the separation center lines 82.

It can in particular be seen in FIGS. 14 to 16 that the frame 71 only has its full thickness in the area of the thickenings 72, 74 and in the area of the solder control points 47 and is otherwise half etched. This keeps the amount of material of the leadframe composite in the separation center lines C as low as possible.

In all other respects, the explanations on FIGS. 1 to 13 apply in the same way to FIGS. 14 to 16, and vice versa.

The effect and design of the reinforcements 72, 74 are explained in more detail in FIGS. 17 and 18.

There is a gap 73 between the leadframe parts 41, 42. Only the housing body 5 is present in the area of the gap 73, but not the leadframe material. The gap 73 therefore represents a weak point. In order to prevent buckling in the area of the gap 73, thickenings 72 are present transversely to the gap 73 along the separation center lines 82, which run parallel to the main axis M, see the highlighting by the arrows in FIG. 17. Seen along the main axis M, the thickenings 74 extend into the lead frame parts 41, 42. The gap 73 is thus located between two of the thickenings 72.

For a length L of the thickenings 72 and a width B of the gap 73 on the inner sides 43, the following applies, for example: 2 B≤L≤15 B or 4 B≤L≤8 B. With a tolerance of +/-B, the thickenings 72 can be positioned centrally to the gap 73 so that the thickenings 72 extend the same distance or approximately the same distance along the main axis M beyond the gap width B.

In FIG. 18, it is emphasized that the further thickenings 74 extend transversely to a further gap between the first leadframe part 41 and the further leadframe parts 83. The two further gaps per leadframe unit 4 are thus each located between two of the further thickenings 74.

For a total length L2 of the further thickenings 74, including the solder control points 47 of the second leadframe part 42, and a width B2 of the further gap on the inner sides 43, the following applies, for example: 2 B₂≤L₂≤15 B₂ or 4 B₂≤L₂ ≤8 B₂. With a tolerance of +/−B₂, the further thickenings 74 can be positioned centrally to the further gap, so that the further thickenings 74 extend the same distance or approximately the same distance in the direction perpendicular to the main axis M beyond the further gap width B2.

The thickenings 72 and the further thickenings 74 may be present independently of each other or in combination.

FIG. 19 shows that the thickenings 72 and the further thickenings 74 can be visible from the housing bottom side 21. This means that the thickenings 72 and/or the further thickenings 74 can serve as markings during cutting.

In all other respects, the explanations relating to FIGS. 1 to 16 apply in the same way to FIGS. 17 to 19, and vice versa.

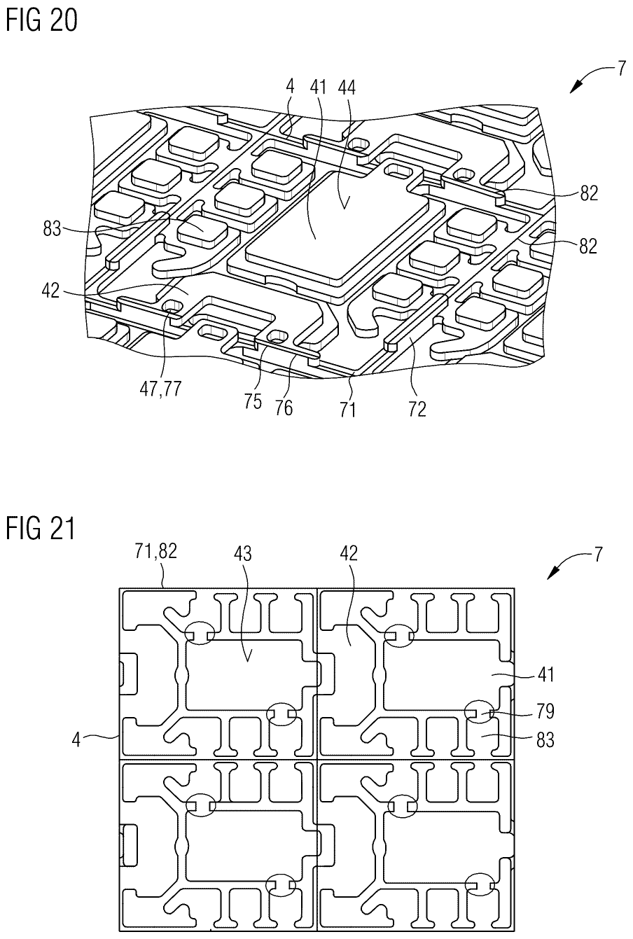

Finally, the leadframe composite 7, as used in connection with FIGS. 5 to 19, is illustrated again in a perspective view in FIG. 20 with a view of the outer sides 44.

FIG. 21 shows another example of the leadframe composite 7. In this leadframe composite 7, two of the further leadframe parts 83 are each connected to the first leadframe part 41 by a further tie bar 79, see the highlighting in FIG. 21. The further tie bars 79 are, for example, half-etched and thus not visible when viewed from the housing bottom side 21. The further tie bars 79 extend, for example, from the two diagonally opposite further leadframe parts 83.

In all other respects, the comments to FIGS. 1 to 20 apply in the same way to FIG. 21, and vice versa.

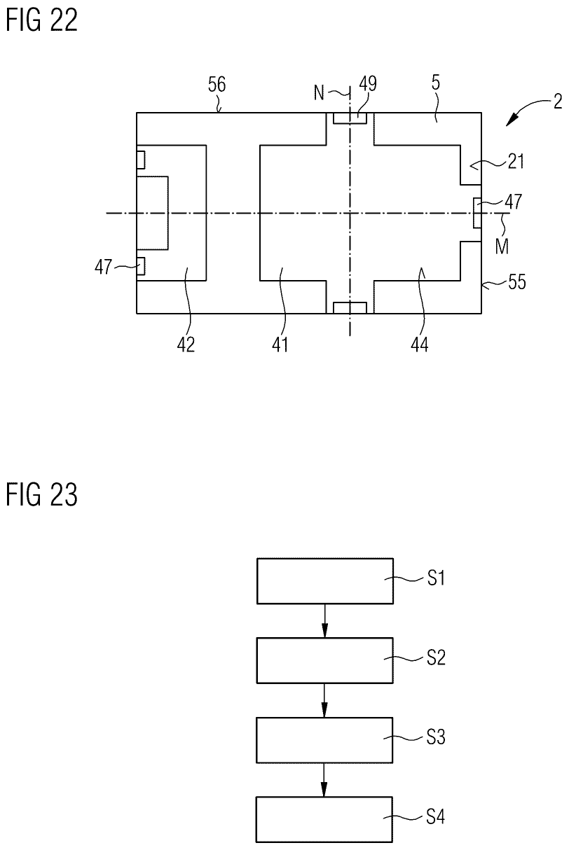

In the example of FIG. 22, it is shown that further solder control points 49 may be present. The further solder control points 49 are located, for example, on the first leadframe part 41 and extend to the side walls 56, which can be aligned parallel to the skin axis M.

It is possible that the further solder control points 49 overlap congruently when viewed in projection onto the side walls 56, that is, in the direction parallel to a minor axis N. For example, the minor axis N is oriented perpendicular to the main axis M when viewed from above onto the housing bottom side 21. Alternatively, the further solder control points 49 can also be arranged offset to one another, analogous to the solder control points 47.

Such further solder control points 49 may also be present in all other examples.

In all other respects, the comments to FIGS. 1 to 21 apply in the same way to FIG. 22, and vice versa.

FIG. 23 schematically illustrates a manufacturing method for the housing 22. In a step S1, a leadframe composite 7 is provided. Subsequently, in a step S2, the housing base body 50 is molded to the leadframe units 4 of the leadframe composite 7. Then, in the optional step S3, the leadframe units 4 are equipped with the chips 3, 31, provided with the connecting means 6 and, if necessary, covered with a covering body, such as a fluorescent material. Finally, in a step S4, the housing base body 50 and the leadframe composite 7 are singulated to form the individual housings 2, so that each of the housings 2 comprises the leadframe parts 41, 42 of one of the leadframe units 4 and one housing body 5.

In all other respects, the comments to FIGS. 1 to 22 apply in the same way to FIG. 23, and vice versa.

The components shown in the figures preferably follow one another in the order indicated, in particular directly one after the other, unless otherwise described. Components not touching each other in the figures preferably have a distance between them. If lines are drawn parallel to one other, the associated surfaces are preferably also aligned parallel to one other. In addition, the relative positions of the drawn components to one other are shown correctly in the figures, unless otherwise specified.

The invention described herein is not limited by the description based on the embodiments. Rather, the invention includes any new feature as well as any combination of features, which includes in particular any combination of features in the patent claims, even if this feature or combination itself is not explicitly stated in the patent claims or embodiments.

1. -16. (canceled)

17. A housing comprising:
a first leadframe part and a second leadframe part; and
a housing body mechanically connecting the first and second leadframe parts to one another,
wherein each first and second leadframe part has a mounting area on an inner side and each has an outer side opposite the inner side,
wherein the first leadframe part has at least one solder control point and the second leadframe part has at least two solder control points,
wherein each solder control point is formed as a recess at an associated outer side and is accessible from an outer side wall of the housing,
wherein the solder control points of the second leadframe part and the at least one solder control point of the first leadframe part are located on mutually opposite outer side walls of the housing body and are arranged completely offset relative to one another so that the solder control points are free of an overlap in a direction parallel to a main axis,
wherein the main axis, seen in plan view of the outer sides, runs perpendicular to the mutually opposite outer side walls comprising the solder control points and intersects a center point of the housing, and
wherein, in plan view of the outer side, both the first and second leadframe parts lie on an outer main axis.

18. The housing according to claim 17,
wherein the mounting areas are configured for mounting at least one optoelectronic semiconductor chip, at least one further semiconductor chip and/or at least one electrical connection, and wherein the outer sides are configured for external mounting of the housing.

19. The housing according to claim 17,
wherein a first quantity of the solder control points of the first leadframe part differs from a second quantity of the solder control points of the second leadframe part.

20. The housing according to claim 17, wherein the first and second leadframe parts terminate flush with the housing body at the outer sides and at the mutually opposite outer side walls.

21. The housing according to claim 17, further comprising one or more further leadframe parts at which a tie first bar is located,
wherein the first tie bar is exposed only on the outer side wall extending transversely to the outer side walls with the solder control points.

22. The housing according to claim 21, further comprising a third leadframe part connected to the first or second leadframe part by a second tie bar.

23. A leadframe composite comprising:
a plurality of leadframe units, each being configured for a housing and each comprising a first leadframe part and a second leadframe part,
wherein each leadframe unit comprises the first and the second leadframe part, each having a mounting area on an inner side, each having an outer side opposite the inner side and each inner side is larger than the associated outer side,
wherein the first leadframe part has at least one solder control point and the second leadframe part has at least two solder control points, each solder control point is formed as a recess in the outer side, and
wherein the solder control points of the second leadframe part and the at least one solder control point of the first leadframe part are located on opposite sides and are arranged completely offset from one another so that the solder control points are non-overlapping in directions parallel to a main axis of a respective leadframe unit,
wherein the main axis runs perpendicular to the opposite sides comprising the solder control points and intersects a center point of the respective leadframe unit, and
wherein, in plan view of the outer side, both the first and second leadframe parts lie on an outer main axis.

24. The leadframe composite according to claim 23,
wherein each leadframe unit has a frame partially or completely circumferentially surrounding it, and
wherein a width of the frame is at least 30 μm and at most 0.3 mm, seen in plan view, of the outer sides.

25. The leadframe composite according to claim 24,
wherein each frame has a thickening with full material thickness of the leadframe composite,
wherein the thickenings are arranged in extension of a gap between the associated first and second leadframe parts, and
wherein a length of the thickenings is at least twice a width of an associated gap.

26. The leadframe composite according to claim 24, wherein the frame comprises at least one further thickening extending from at least one of the solder control points.

27. The leadframe composite according to claim 23, wherein a solder control point frame of one of the leadframe units extends between the solder control points of one of the leadframe parts of a directly adjacent leadframe unit as seen in plan view of the outer sides.

28. The leadframe composite according to claim 23, wherein the solder control points on a common side of two directly adjacent leadframe units are connected to each other by at least one transverse bar, and wherein the at least one transverse bar is set back with respect to the outer sides.

29. The leadframe composite according to claim 23, wherein, seen in plan view of the outer sides, each recess is limited to one of the leadframe units so that the recesses do not touch or cross any boundaries between adjacent leadframe units.

30. The leadframe composite according to claim 23, wherein the solder control points are arranged mirror-symmetrically relative to the main axis of a respective leadframe unit, seen in plan view of the outer sides, and only one of the solder control points of the respective leadframe unit lies on the main axis.

31. A method comprising:
providing the leadframe composite according to claim 23;
molding a housing base body to the leadframe units; and
singulating the housing base body and the leadframe composite to form individual housings so that each housing comprises the leadframe parts of one of the leadframe units and a housing body.

32. The method according to claim 31,
wherein each leadframe unit has a frame partially or completely circumferentially surrounding it, and
wherein during singulating the frames completely lie in a separation track.

33. A housing comprising;
a first leadframe part and a second leadframe part; and
a housing body mechanically connecting the first and second leadframe parts to one another,
wherein each first and second leadframe parts has a mounting area on an inner side and each has an outer side opposite the inner side,
wherein the first leadframe part has at least one solder control point and the second leadframe part has at least two solder control points,
wherein each solder control point is formed as a recess in the associated outer side and is accessible from an outer side wall of the housing,
wherein the solder control points of the second leadframe part and the at least one solder control point of the first leadframe part are located on mutually opposite outer side walls of the housing body and are arranged completely offset relative to one another so that the solder control points are free of overlap in a direction parallel to a main axis, and
wherein the main axis, seen in plan view of the outer sides, runs perpendicular to the mutually opposite outer side walls comprising the solder control points and intersects a center point of the housing.
